(19) United States
(12) Patent Application Publication
(10) Pub. No.: US 2008/0202800 A1
(43) Pub. Date: Aug. 28, 2008

(54) Re-routing method and the circuit thereof

(76) Inventors: Ming-Hong Kuo, Hsinchu (TW); Bor-Doou Rong, Hsinchu (TW); Yi-Chen Wu, Hsinchu (TW); Hsin-I Cheng, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/149,055

(22) Filed: Apr. 25, 2008

Related U.S. Application Data
(62) Division of application No. 11/322,215, filed on Jan. 3, 2006.

(30) Foreign Application Priority Data
Jun. 16, 2005 (TW) 094120068

(51) Int. Cl. H05K 1/09

(52) U.S. Cl. 174/257

(57) ABSTRACT

A re-routing method and the circuit thereof, used to rearrange the external circuit coupled with the integrated circuit (IC), comprises the steps of providing a plurality of first conductive plate on the substrate of the IC to form an isolation layer; providing a plurality of second conductive plates on the isolation layer, wherein each of the second conductive plates is moved in isovector with each of the corresponding first conductive plates as the center, each of the second conductive plates electrically connected with each of the first conductive plates. Therefore, according to move the second conductive plates in isovector, the probe card may be reused for circuit testing to save the cost and reduce the material management.

### RELATED APPLICATIONS

This application is a Divisional patent application of co-pending application Ser. No. 11/322,215, filed on 3 Jan. 2006. The entire disclosure of the prior application Ser. No. 11/322,215, from which an oath or declaration is supplied, is considered a part of the disclosure of the accompanying Divisional application and is hereby incorporated by reference.

### FIELD OF THE INVENTION

The present invention relates to a Re-routing method and the circuit thereof, and more particularly, to a Re-routing method and the circuit thereof with moving the second conductive plates of testing board used in isovector, placing on the one side of the corresponding first conductive plates.

### BACKGROUND OF THE INVENTION

The probe card is used to functionally test for the bare chip to sift the defective products from perfect ones before unpackaged IC. Then, after testing the perfect products, it could be further packaged. Therefore, the relative quality control for IC producing is needed. According to the utility of the probe card, the yield of product will be up to 90% from 70%. The 20% difference is a great affection for the semiconductor manufactures.

The wafer probe tests each die by the testing tool and the probe card to insure the electricity and efficacy of each die is produced by following the specification. Further, the testing tool can be designed for special purposes, such as made the probe by small-diameter gold, which is about the width of a human hair. According to the contact with the probe and the pad, it is used to input the signal or read the output value of the wafer. Therefore, the purpose of testing product will be achieved

When manufacturing the IC, the circuit on the wafer is usually as a standard circuit with the same specification, such as be able to made thousands of the same Operation Amplifier or other standard circuit on a wafer. And, it is to be a die by cutting these Operation Amplifiers or standard circuit, then bonding these dies and the leadframe for further packaging. Finally, it will be as a packaged IC in market.

Referring FIG. 1, depicts a schematic vertical view of a conventional prior art IC with external circuit. The external circuit comprises a first conductive plate 21, a third conductive plate 33, and a conductor 33. Most of client of IC users like to ask the manufacture to fit their requirement by following their specification with the pins of IC for easily designed and layout. Therefore, for the standard circuit on the wafer, the external circuit should be rearranged by the re-routing method, as well as, after bonding the dies and the leadframe, the pins of IC will follow the specification for the requirement of client.

As foregoing prior art re-routing method, it simply concerns the pins fitted the specification of clients only, but without concerning the testing problems; therefore, after re-routing for each IC, the probe card should be demanded again. Thus, it not only increases the cost of testing, but also increasing the cost of material design, purchase, check, exercise, and management.

### SUMMARY OF THE INVENTION

It is an object of the present invention to provide a re-routing method, which is to rearrange the external circuit of the IC, comprising the steps of providing a plurality of first conductive plates on the substrate of the IC, and each of the first conductive plates electrically connected with the IC; forming a isolation layer to cover on the IC and the first conductive plates; providing a plurality of second conductive plates on the isolation layer, each of the second conductive plates electrically connected with each of the first conductive plates, and moving each of the second conductive plates in isovector with each of corresponding the first conductive plates as the center; and providing a plurality of third conductive plates on the isolation layer, each of the third conductive plates electrically connected with each of the second conductive plates by a second conductor.

It is another object of the present invention to provide a re-routing circuit, which is to rearrange the external circuit of the IC, comprising a plurality of first conductive plates provided on the substrate of the IC, each of first conductive plates electrically connected with the IC; an isolation layer covered on the IC and the first conductive plates; a plurality of second conductive plates provided on the isolation layer, each of the second conductive plates electrically connected with each of the first conductive plates, and moving each of the second conductive plates in isovector with each of the corresponding first conductive plates as the center; and a plurality of third conductive plates provided on the isolation layer, each of the third conductive plates electrically connected with each of the second conductive plates by a second conductor.

According to move the second conductive plates in isovector, the place of the second conductive plate is on the one side of the corresponding first conductive plate with the same distance and direction. Therefore, for testing the circuit of the second conductive plate, the probe card may be reused again, as well as it is used to test for the first conductive plate, such that the probe card can be saved, and the post process tool or material can be shared, including the leadframe, and substrate . . . etc. consequently, saving the cost and reduce the material management are achieved.

### Advantages

The following are features and advantages of the present invention:
1. is to save more probe cards for testing the conductive plates.
2. It is to share the post process tool or material for further mass-producing and purchasing.
3. It is to reduce the cost of the tool and material management for preventing from misusing the probe card with similar aspect to cause process problems.

### BRIEF DESCRIPTION OF THE DRAWINGS

FIG. 1 depicts a schematic vertical view of a conventional prior art IC with external circuit;

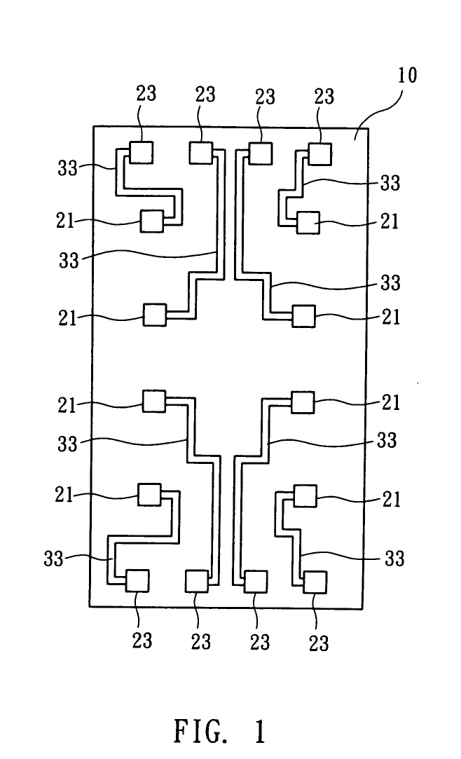

FIG. 2 shows a flow chart of a re-routing method for an IC with external circuit according to an embodiment of the present invention;

FIG. 3A depicts a schematic vertical view of a re-routing circuit of an IC according to an embodiment of the present invention;

FIG. 3B shows a three-dimensional partial enlarged graph of the FIG. 3A;

FIG. 3C depicts a partial enlarged vertical view of the FIG. 3A;

FIG. 3D depicts a schematic cross sectional view by the A-A′ hatch of the FIG. 3B;

FIG. 4 depicts a schematic vertical view of an embodiment of the present invention with a line shape first conductive plate;

FIG. 5 depicts a schematic vertical view of an embodiment of the present invention with a plane shape first conductive plate; and

FIG. 6 depicts a schematic vertical view of an embodiment of the present invention with omitting the first conductive plate.

### DETAILED DESCRIPTION OF THE INVENTION

The features and the effects to be achieved may further be understood and appreciated by reference to the presently preferred embodiments together with the detailed description.

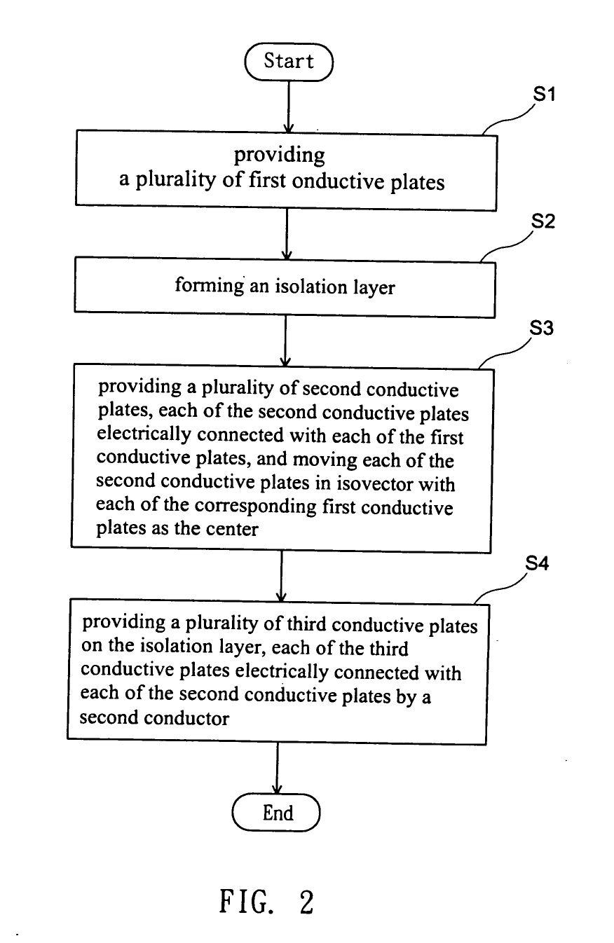

Referring to FIG. 2, a flow chart of a re-routing method for an IC with external circuit according to an embodiment of the present invention; the method for rearranging the external circuit of an IC comprises the steps of providing a plurality of first conductive plates on the substrate of the IC, and each of the first conductive plates electrically connected with the IC (step S1); forming a isolation layer to cover on the IC and the first conductive plates (step S2); providing a plurality of second conductive plates on the isolation layer, each of the second conductive plates electrically connected with each of the first conductive plates, and moving each of the second conductive plates in isovector with each of corresponding the first conductive plates as the center (step S3); and providing a plurality of third conductive plates on the isolation layer, each of the third conductive plates electrically connected with each of the second conductive plates by a second conductor (step S4).

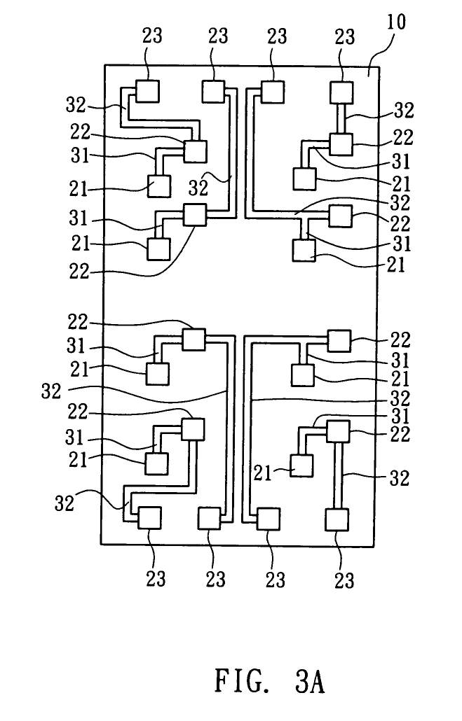

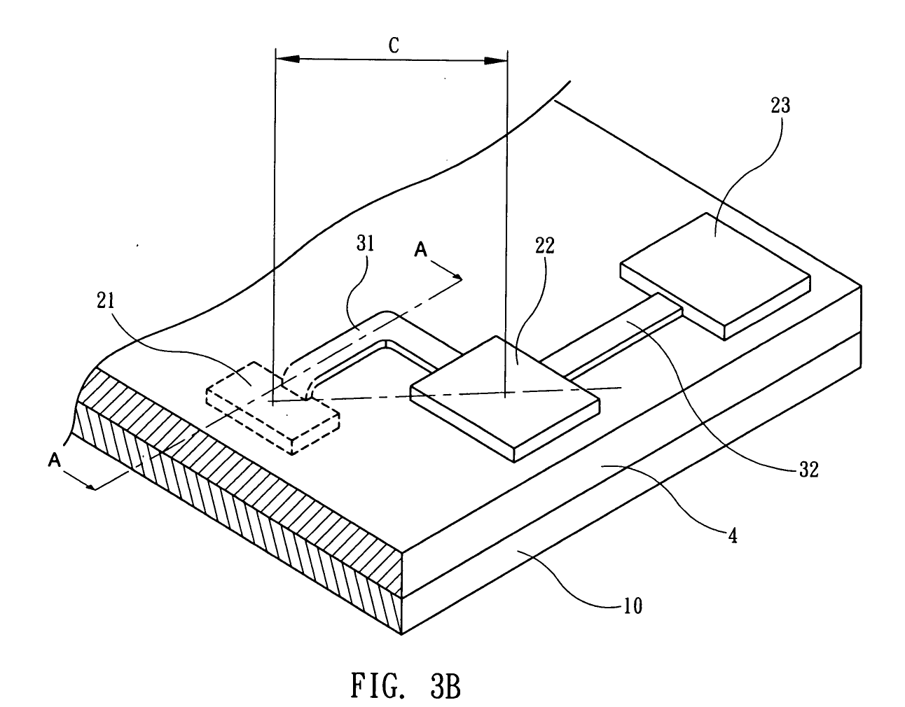

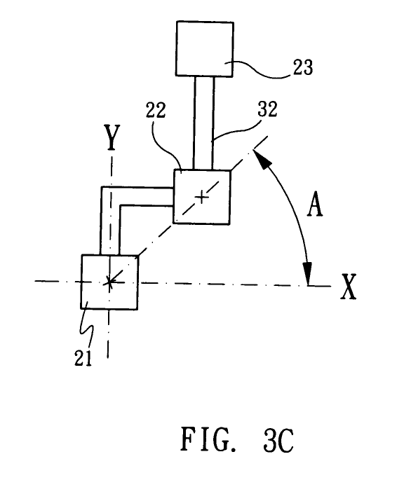

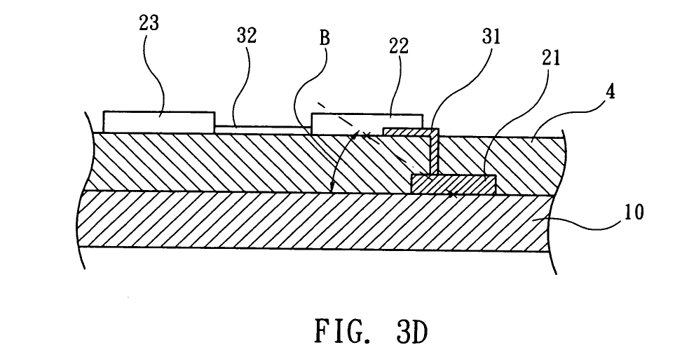

Referring to FIG. 3A, shows a schematic vertical view of a re-routing circuit of an IC according to an embodiment of the present invention. The substrate 10 is a chip, and the IC and the external circuit thereof are made on the substrate 10. After finishing the IC and the external circuit thereof, the substrate is cut to be many dies by according to every circuit unit within the substrate 10. Then, bonding the leadframe and the dies, the continuous package process is able to be going.

The first conductive plates 21 are provided on the substrate 10, each of the first conductive plates 21 is electrically connected with the IC; therefore, it is able to be the first test step for the IC by testing the first conductive plates 21.

The isolation layer 4 is covered on the IC and the first conductive plates 21, which is made by a SiOx, a SiNx, or an Organic mater, and the Organic mater is such as a Polyimide.

The second conductive plates 22 are provided on the isolation layer 4, and each of the second conductive plates 22 is connected with each of the first conductive plates 21. Each of the second conductive plates 22 is moved in isovector with each of the corresponding first conductive plates 21 as the center. The second conductive plates 22 are used for the second step test, as well as the conductivity of the second conductive plates 22 are well. In generally, the second conductive plates 22 are provided on the different surface with the first conductive plates 21 by supporting from the isolation layer 4; thus, it is to interlace space and flexibly design for re-routing. When it is testing, the probe card is used to test the circuit with signal input and output of the second conductive plates for defects and further quality control.

The third conductive plates 23 are provided on the isolation layer 4 also, and each of the third conductive plates 23 is connected with each of the second conductive plates 22 by a second conductor 32. The third conductive plates 23 are the point of connecting with the IC and the external circuit thereof, such as the wire bonding connected.

Referring to FIGS. 3B, 3C, and 3D, show a three-dimensional partial enlarged graph of the FIG. 3A, a partial enlarged vertical view of the FIG. 3A, and a schematic cross sectional view by the A-A′ hatch of the FIG. 3, which disclose the relation of angle and distance between the second conductive plates 22 and the corresponding first conductive plates 21 as the center. The first conductive plates 21 and the second conductive plates 22 are under the same rectangular coordinate system, which provides X-axis, Y-axis, and Z-axis, wherein the X-axis and Y-axis are on the same plane and the Z-axis is rectangular with the plane. And, the right side of the X-axis from the Y-axis is positive value; the left side of the X-axis from the Y-axis is negative value; the up side of the Y-axis from X-axis is positive value; the low side of the Y-axis from axis is negative value; the up side of the plane from Z-axis is positive value; the low side of the plane from Z-axis is negative value. According to the angle configuration, the angle of right side of X-axis from Y-axis is defined as the zero degree, which is the first angle, and beginning forward to anti-clockwise direction circled, the plane included by X-axis and Y-axis is distributed as 360 degrees. For the Z-axis, the plane included by X-axis and Y-axis is defined as the zero degree, which is the second angle, and beginning forward to anti-clockwise direction circled, the vertical space with the plane included by X-axis and Y-axis is distributed as 360 degrees. The point intersected by X-axis, Y-axis, and Z-axis is defined as the origin, which is the center point in each of the first conductive plates 21.

Each of the second conductive plates 22 is corresponding to each of the first conductive plates 21. And, the meaning of moving an isovector, that is the relationship of the relative place between the second conductive plates 22 and the corresponding first conductive plates 21, is the same first angle A, the same second angle B, and the same distance c, such as the second conductive plates 22 are shifted from the origin (the center of the first conductive plates 21) with the first angle A, 45 degrees, the second angle B, 15 degrees, and the distance C, 2 mm. Therefore, the distance of each of the second conductive plates 22 and the relative position of each other thereof are corresponding with the first conductive plates 21. Thus, the probe card is able to be reused for testing, and avoid the waste.

On other way, the relative positions between the second conductive plates 22 and the corresponding first conductive plates 21 are not expressed by the angle A, B, and the distance C, but expressed by such as the distance of each of the second conductive plates 22 shifted is X-axis plus 2 mm, Y-axis plus 3 mm, and Z-axis plus 1 mm, which is only different expression, but the same result.

In accordance with integrated all circuits, a plurality of first conductors 31 are provided. The first conductors 31 are electrically connected with the second conductive plates 22 and the corresponding first conductive plates 21. Furthermore, a plurality of second conductors 32 are provided. The second conductors are electrically connected with the second conductive plates 22 and the corresponding plurality of pins.

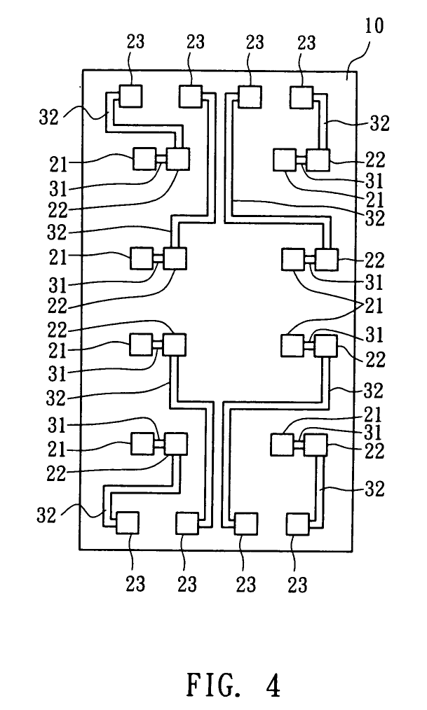

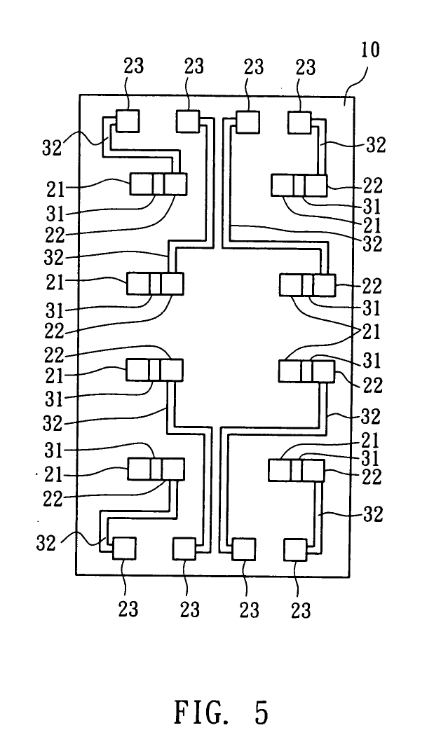

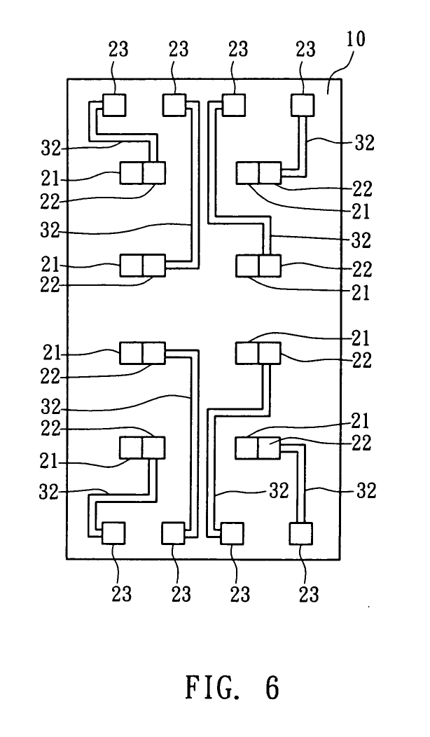

Referring to FIG. 4, FIG. 5, and FIG. 6, show a schematic vertical view of an embodiment of the present invention with a line shape first conductive plate, a schematic vertical view of an embodiment of the present invention with a space shape first conductive plate, and a schematic vertical view of an embodiment of the present invention with omitting the first conductive plate. The first conductors 31 electrically are connected with the first conductive plates 21 and second conductive plates 22, if the positions of the first conductive plates 21 and the second conductive plates 22 are not closed. And, the first conductors 31 are not only as a line shape aspect, but also can be as a plane aspect. However, if the first conductive plates 21 and the second conductive plates 22 are very closed, then omitting the first conductors 31, and directly enlarging the area of the first conductive plates 21 or the second conductive plates 22; further, the first conductive plates 21 can be directly connected with the second conductive plates 22.

The invention has been described in detail with particular reference to certain preferred embodiments thereof, but it will be understood that variations and modifications can be effected within the spirit and scope of the invention.

What is claimed is:

1. A re-routing circuit for rearranging the external circuit of an IC, comprising:
a plurality of first conductive plates provided on a substrate of said IC, each of first conductive plates electrically connected with said IC;
an isolation layer covered on said IC and said first conductive plates;
a plurality of second conductive plates provided on said isolation layer, each of said second conductive plates electrically connected with each of said first conductive plates, and moving each of said second conductive plates in isovector with each of said corresponding first conductive plates as the center; and
a plurality of third conductive plates provided on said isolation layer, each of said third conductive plates electrically connected with each of said second conductive plates by a second conductor.

2. The re-routing circuit of claim 1, wherein said isolation layer is made by a SiOx, a SiNx, or an Organic mater.

3. The re-routing circuit of claim 2, wherein said Organic mater is a Polyimide.

4. The re-routing circuit of claim 1, wherein said isovector is as the equiangular and equidistance.

5. The re-routing circuit of claim 1, wherein further comprises a plurality of first conductor for electrically connecting with said first conductive plates and second conductive plates.

6. The re-routing circuit of claim 1, wherein said second conductive plates are used for testing.

7. The re-routing circuit of claim 1, wherein said third conductive plates are used for electrically connecting with said IC and external circuit thereof.
